(19) United States
(12) Patent Application Publication
(10) Pub. No.: US 2007/0228366 A1
(43) Pub. Date: Oct. 4, 2007

(54) Method for Purifying Material Comprising Organic Semiconductor, Method for Purifying Material Comprising Pentacene, Semiconductor Device, and Method for Fabricating the Semiconductor Device

(76) Inventors: Shuji Fukai, Kanagawa (JP); Ryota Imahayashi, Kanagawa (JP)

Correspondence Address: COOK, ALEX, MCFARRON, MANZO, CUMMINGS & MEHLER LTD, SUITE 2850, 200 WEST ADAMS STREET, CHICAGO, IL, 60606, US

(21) Appl. No.: 11/660,470

(22) PCT Filed: Aug. 12, 2005
(86) PCT No.: PCT/JP05/15111

§ 371 Date: Feb. 15, 2007

(30) Foreign Application Priority Data
Aug. 23, 2004 (JP) 2004-242792

(51) Int. Cl. H01L 51/00; H01L 51/40

(52) U.S. Cl. 257/40; 438/99; 585/818; 585/836; 585/856; 257/E51.001

(57) ABSTRACT

It is an object of the present invention to provide a simple method for purifying an organic semiconductor. It is another object of the invention to provide a semiconductor device having good characteristics. A method for purifying an organic semiconductor according to the invention includes a process of filtering a sulfoxide solution in which an organic semiconductor is mixed. A second organic semiconductor that is obtained by filtering a sulfoxide solution in which a first organic semiconductor is mixed is used as an active layer in a semiconductor device of the invention.

### TECHNICAL FIELD

The present invention relates to a method for purifying a material comprising an organic semiconductor, and particularly relates to a method for purifying a material comprising pentacene. Further, the invention relates to a semiconductor device including an organic semiconductor formed using the method for purifying a material comprising an organic semiconductor according to the invention and fabricating the semiconductor device.

### BACKGROUND ART

In recent years, semiconductor elements using organic semiconductors have been developed increasingly. In the development field of semiconductor elements using organic semiconductors, there are various challenges such as improvement in carrier mobility in the organic semiconductors.

As for a semiconductor element using an organic semiconductor, impurities in the organic semiconductor is one of the causes of reduction in carrier mobility.

Correspondingly, methods for removing impurities contained in organic semiconductors have been developed so far. For example, a method for purifying an organic semiconductor material, by which impurities can be removed using a supercritical solvent is disclosed (Reference 1: Japanese Patent Laid-Open No. 2003-347624).

However, the method disclosed in Reference 1 is so time consuming since the supercritical state that is a special state is used.

In addition, in the case of sublimation purification, a special apparatus must be used in vacuum; thus, the operation is complex.

### DISCLOSURE OF INVENTION

It is an object of the present invention to provide a simple method for purifying an organic semiconductor. It is another object of the invention to provide a semiconductor device having good operating characteristics.

A method for purifying an organic semiconductor according to the invention includes a treatment for filtering a sulfoxide solution mixed with an organic semiconductor.

As to a semiconductor device according to the invention, a second organic semiconductor obtained by filtering a sulfoxide solution mixed with a first organic semiconductor is used as an active layer.

According to the invention, an organic semiconductor can easily be purified. Further, according to the invention, purification can easily be carried out without using a special apparatus; therefore, materials for manufacturing a good semiconductor device can be obtained at low cost.

Moreover, according to the invention, a semiconductor device having good operating characteristics can be manufactured at low cost. Further, a good semiconductor device with little trouble caused due to impurities contained in a semiconductor layer can be obtained.

### BRIEF DESCRIPTION OF DRAWINGS

FIGS. 1A to 1D are figures showing a method for manufacturing a semiconductor apparatus according to the present invention.

FIGS. 2A to 2D are figures showing a method for manufacturing a semiconductor apparatus according to the present invention.

FIGS. 3A to 3D are figures showing a method for manufacturing a semiconductor apparatus according to the present invention.

FIG. 4 is a figure showing voltage-current characteristics of a semiconductor apparatus according to the present invention.

FIG. 5 is a top view showing a liquid crystal display device including a semiconductor device of the present invention.

FIGS. 6A and 6B are cross-sectional views showing liquid crystal display devices each including a semiconductor device of the present invention.

FIGS. 7A to 7C are figures showing electronic devices and the like applying the present invention.

FIGS. 8A to 8C are figures for explaining Embodiment 1.

### BEST MODE FOR CARRYING OUT THE INVENTION

Embodiment modes and embodiments according to the present invention will be described below. The present invention can be carried out in many different modes, and it is easily understood by those skilled in the art that the modes and details herein disclosed can be modified in various ways without departing from the spirit and the scope of the present invention. Accordingly, the present invention should not be interpreted as limited to the description of the embodiment modes and embodiments given below.

### Embodiment Mode 1

A method for purifying pentacene according to the invention includes a treatment for filtering a sulfoxide solution in which an organic semiconductor is mixed. In other words, the sulfoxide solution is used as filtrate.

Through such a treatment, impurities contained together with the organic semiconductor can be reduced. Here, pentacene is preferable as the organic semiconductor. Dimethyl sulfoxide solution or the like is particularly preferable as the sulfoxide solution. The filtration method is not particularly limited; for example, a filter paper, a membrane filter, or the like may be used for the filtration. Note that, in the case of using a filter paper, a filter paper having a pore size of 1 μm or less is preferably used.

Pentacene remaining after the filtration is preferably washed (cleaned) using an alcohol solution such as ethanol. Thus, the sulfoxide solution attached to pentacene can be removed. Pentacene washed (cleaned) with an alcohol solution is preferably dried thereafter. At that time, if the drying is carried out under reduced pressure, the temperature required for the drying can be lowered.

Note that the treatment for filtering the sulfoxide solution in which pentacene is mixed may be repeated a plurality of times.

Pentacene is treated by the purification method as above; thus, impurities contained together with pentacene can be reduced. Further, the purification method described above according to the invention is simpler than a purification method using sublimation and can be carried out at low cost.

### Embodiment Mode 2

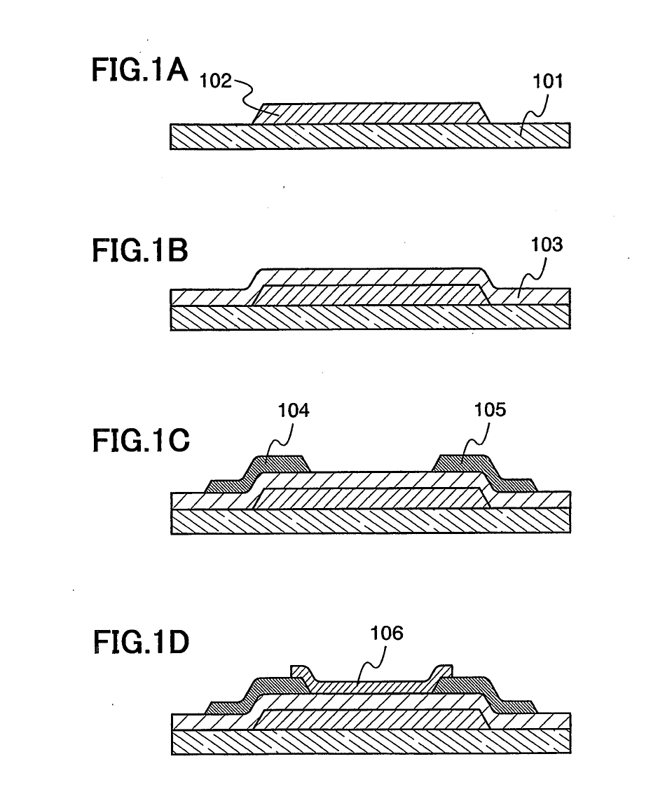

A mode of a semiconductor device according to the invention and a manufacturing method thereof will be described with reference to FIGS. 1A to 1D.

A gate electrode 102 is formed over a substrate 101. The formation method of the gate electrode 102 is not particularly limited; for example, a deposited conductive layer may be processed into a desired shape by photolithography. Alternatively, the gate electrode 102 may be formed by an ink-jet method by which a droplet containing a conductive material is discharged while the timing and the position are controlled so as to form a pattern having a desired shape. The material for forming the gate electrode 102 is not either limited in particular. For example, aluminum, copper, gold, or silver can be used. Further, the material of the substrate 101 is not limited in particular; a flexible substrate such as a plastic substrate or a polycarbonate substrate can be used other than a glass substrate or a quartz substrate. (FIG. 1A)

Next, a gate insulating layer 103 covering the gate electrode 102 is formed. The material of the gate insulating layer 103 is not limited in particular; for example, an insulator such as silicon oxide or silicon nitride may be deposited by CVD or the like. Alternatively, an organic material such as polyimide, polyamic acid, or polyvinyl phenol may be applied depending on the temperature applied to the material during the film formation, by cast, a spinner, printing, ink-jet, or the like to form the gate insulating layer 103. (FIG. 1B)

Next, a source electrode 104 and a drain electrode 105 are formed over the gate insulating layer 103. The material of the source electrode 104 and the drain electrode 105 is not limited in particular; for example, an organic conductive material containing poly (ethylene dioxythiophene)/poly (styrene sulfonic acid) mixture (PEDOT/PSS), or the like other than an inorganic conductive material such as gold, silver, or tungsten may be used. Further, the formation method of each of the source electrode 104 and the drain electrode 105 is not limited in particular; for example, a conductive layer formed using a film formation apparatus such as a sputtering apparatus or a vapor deposition apparatus may be processed into a desired shape. Alternatively, the source electrode 104 and the drain electrode 105 may be formed by an ink-jet method in which a droplet containing a conductive material is discharged while the timing and the position are controlled so as to form patterns each having a desired shape. (FIG. 1C)

Next, a semiconductor layer 106 is formed over the gate insulating layer 103, source electrode 104, and drain electrode 105. The semiconductor layer 106 may be formed of pentacene purified by a purification method according to the invention. The formation method of the semiconductor layer 106 is not limited in particular. For example, an area where the semiconductor layer 106 is to be formed is selectively made water repellent and the area other than the above area is, made hydrophilic, and pentacene may be thereafter made grow by itself. Thus, the semiconductor layer 106 can be formed into a desired shape without patterning after film formation. Further, the semiconductor layer 106 may be formed by selectively forming a film over a desired area by vapor deposition using a shadow mask or the like. In this case, the material penetrating through a space between the shadow mask and a subject would be deposited to form an unnecessary semiconductor layer. To deal with this, adhesion between the shadow mask and the subject is preferably increased. Alternatively, a semiconductor layer may be formed to cover the entire subject, and then processed to a desired shape thereby forming the semiconductor layer 106. In such a case, vacuum bake or other treatment is preferably carried out after the shaping process. Through such a treatment, the characteristics of the semiconductor device are improved. (FIG. 1D)

In the semiconductor device manufactured in the above manner, the semiconductor layer 106 serves as an active layer. Such a semiconductor device can be used, for example, as a circuit element of a logic circuit, a memory circuit of a DRAM, or the like other than a switching circuit of a liquid crystal display element (a liquid crystal element).

The semiconductor device manufactured in the above manner according to the invention has good operating characteristics since the semiconductor layer thereof is formed of pentacene which is purified by a purification method according to the invention. Further, the material cost is very low since pentacene which is purified by a purification method according to the invention is used.

### Embodiment Mode 3

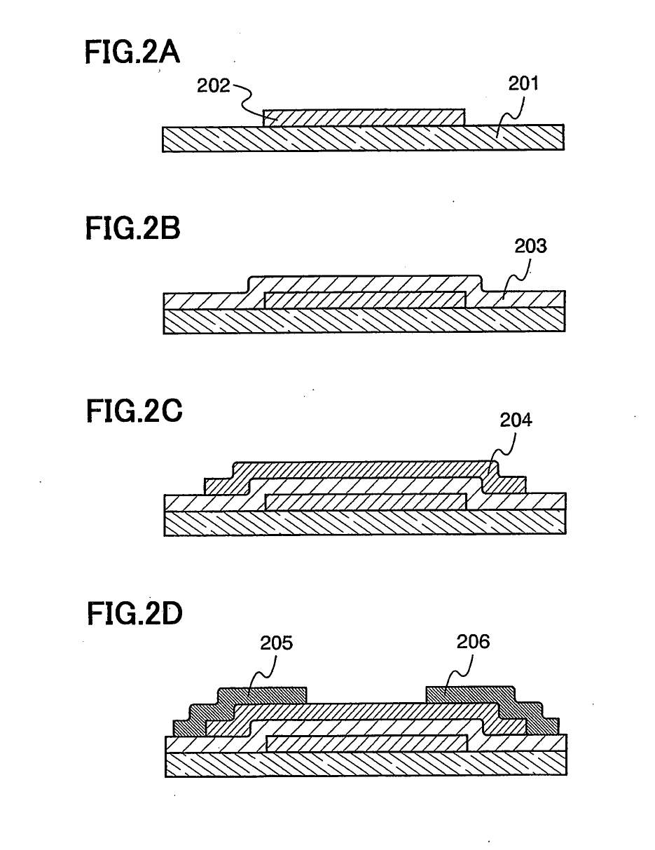

A mode of a semiconductor device according to the invention and a manufacturing method thereof will be described with reference to FIGS. 2A to 2D.

A gate electrode 202 is formed over a substrate 201. The formation method of the gate electrode 202 is not particularly limited; for example, a deposited conductive layer may be processed into a desired shape by photolithography. Alternatively, the gate electrode 202 may be formed by an inkjet method in which a droplet containing a conductive material is discharged while the timing and the position are controlled so as to form a pattern having a desired shape. The material for forming the gate electrode 202 is not either limited in particular; for example, aluminum, copper, gold, or silver can be used. Further, the material of the substrate 201 is not limited in particular; a flexible substrate such as a plastic substrate or a polycarbonate substrate can be used other than a glass substrate or a quartz substrate. (FIG. 2A)

Next, a gate insulating layer 203 covering the gate electrode 202 is formed. There is no particular limitation on the gate insulating layer 203; for example, an insulator of silicon oxide or silicon nitride may be deposited by CVD or the like. Alternatively, an organic material such as polyimide, polyamic acid, or polyvinyl phenol may be applied depending on the temperature applied to the material during the film formation, by cast, a spinner, printing, ink-jet, or the like to form the gate insulating layer 203. (FIG. 2B)

Next, a semiconductor layer 204 is formed over the gate insulating layer 203. The semiconductor layer 204 may be formed of pentacene purified by a purification method according to the invention. The formation method of the semiconductor layer 204 is not limited in particular. For example, an area where the semiconductor layer 204 is to be formed is selectively made water repellent and the area other than the above area is made hydrophilic, and pentacene may be thereafter made grow by itself. Thus, the semiconductor layer 204 can be formed into a desired shape without patterning after film formation. Further, the semiconductor layer 204 may be formed by selectively forming a film over a desired area by vapor deposition using a shadow mask or the like. In this case, the material penetrating through a space between the shadow mask and a subject would be deposited to form an unnecessary semiconductor layer. To deal with this, adhesion between the shadow mask and the subject is preferably increased. Alternatively, a semiconductor layer may be formed to cover the entire subject, and then processed into a desired shape thereby forming the semiconductor layer 204. In such a case, vacuum bake or other treatment is preferably carried out after the shaping process. Through such a treatment, the characteristics of the semiconductor device are improved. (FIG. 2C)

Next, a source electrode 205 and a drain electrode 206 are formed over the semiconductor layer 204. There is no particular limitation on the source electrode 205 and the drain electrode 206; for example, an organic conductive material containing PEDOT/PSS or the like other than an inorganic conductive material such as gold, or silver may be used. Further, the formation method of each of the source electrode 205 and the drain electrode 206 is not limited in particular; for example, a conductive layer formed using a film formation apparatus such as a sputtering apparatus or a vapor deposition apparatus may be processed into a desired shape. Alternatively, the source electrode 205 and the drain electrode 206 may be formed by an ink-jet method in which a droplet containing a conductive material is discharged while the timing and the position are controlled so as to form patterns each having a desired shape. (FIG. 2D)

Here, a self-forming film may be formed over the semiconductor layer 204 before forming the source electrode 205 and the drain electrode 206 so that the self-forming film is formed between the source electrode 205 and the drain electrode 206, and the semiconductor layer 204. With this structure, contact resistance between the semiconductor layer 204 and each of the source electrode 205 and the drain electrode 206 can be reduced. Here, the self-forming film can be formed using alkyl silane having an amino group, or the like. Specifically, octadecyl trichlorosilane, (3-aminopropyl)trimethoxy silane, N-2 (aminoethyl) γ-aminopropyl methyl dimethoxy silane, N-2 (aminoethyl) γ-aminopropyl trimethoxy silane, 3-aminopropyl trimethoxy silane or the like can be used.

In the semiconductor device manufactured in the above manner, the semiconductor layer 204 serves as an active layer. Such a semiconductor device can be used, for example, as a circuit element of a logic circuit, a memory circuit of a DRAM or the like other than a switching circuit of a liquid crystal display element.

The semiconductor device manufactured in the above manner according to the invention has good operating characteristics since the semiconductor layer thereof is formed of pentacene which is purified by a purification method according to the invention. Further, the material cost is very low since pentacene which is purified by a purification method according to the invention is used.

While a mode of a transistor having 3 terminals including a gate electrode, a source electrode, and a drain electrode has been described, an organic semiconductor obtained according to the invention may be used to form a semiconductor layer included in a nonvolatile memory element or the like other than a transistor as above. Thus, a semiconductor device such as a memory element which is excellent with less characteristic defects due to impurities contained in a semiconductor layer can be obtained.

### Embodiment Mode 4

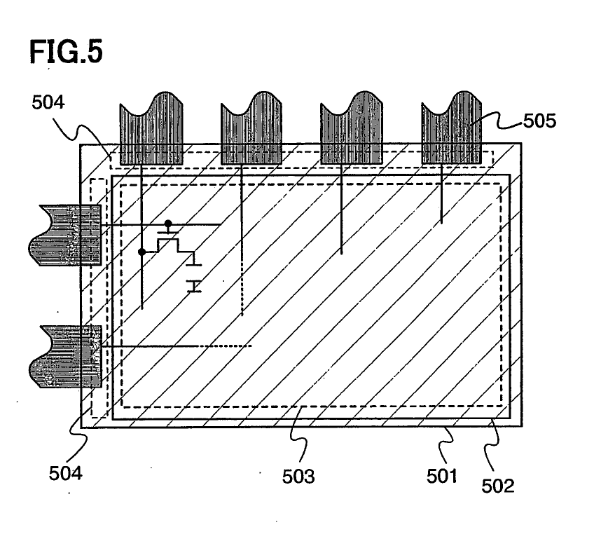

A mode of a liquid crystal display device (a liquid crystal device) including the semiconductor device according to the present invention is explained with reference to FIG. 5.

FIG. 5 is a top view for showing schematically the liquid crystal display device. The liquid crystal display device according to this embodiment is formed by pasting an element substrate 501 and an opposing substrate 502 so as to be opposed to each other. The liquid crystal display device according to this embodiment has a pixel area 503. A terminal area 504 provided along the side of the pixel area 503 is attached with a flexible printed circuit (FPC) 505. A signal is input to the pixel area 503 from a driver circuit via the flexible printed circuit 505. As in this embodiment, the driver circuit and the flexible printed circuit can be provided independently, alternatively, can be combined as with a TCP in which an IC chip is mounted over an FPC provided with a wiring pattern.

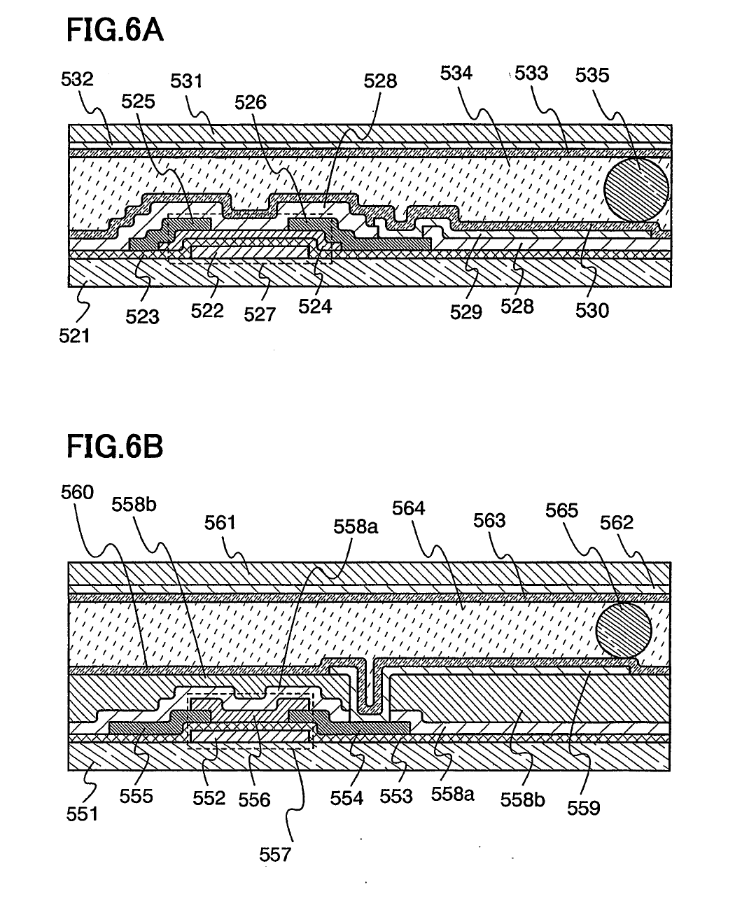

The pixel area 503 is not restricted. For example, as shown in a cross-sectional view in FIG. 6A or 6B, the pixel area 503 includes a liquid crystal display element and a transistor for driving the liquid crystal display element. FIGS. 6A and 6B illustrate embodiments of cross-sectional structures of liquid crystal display devices which have different transistor structures.

The liquid crystal display device shown in a cross-sectional view in FIG. 6A has an element substrate 521 provided with a transistor 527 having electrodes 525 and 526 each serving as a source or a drain over a semiconductor layer 524 as with the semiconductor device described in Embodiment 3. Here, the semiconductor layer 524 contains an organic semiconductor obtained by employing a purification method according to the present invention. A liquid crystal display element is formed with a pixel electrode 529 and a counter electrode 532 and a liquid crystal layer 534 therebetween. Orientation films 530 and 533 are provided over the surfaces, which are in contact with the liquid crystal layer 534, of the pixel electrode 529 and the counter electrode 532. Spacers 535 are dispersed in the liquid crystal layer 534 to hold a cell gap. The transistor 527 is covered with an insulating layer 528 provided with a contact hole. The electrode 526 and the pixel electrode 529 are electrically connected to each other. The counter electrode 532 is supported by an opposing substrate 531. In the transistor 527, the semiconductor layer 524 is overlapped with a gate electrode 522 via a gate insulating layer 523.

The liquid crystal display device represented by a cross-sectional view in FIG. 6B has an element substrate 551 which includes a transistor 557 having a structure in which at least a part of electrodes 555 and 554 each serving as a source or a drain is covered with a semiconductor layer 556 as with the semiconductor device described in Embodiment 2. Here, the semiconductor layer 556 contains an organic semiconductor obtained by employing a purification method according to the present invention. Further, a liquid crystal display element is formed with a pixel electrode 559 and a counter electrode 562 and a liquid crystal layer 564 therebetween. Orientation films 560 and 563 are provided over the surfaces of the pixel electrode 559 and the counter electrode 562 which are in contact with the liquid crystal layer 564. Spacers 565 are dispersed in the liquid crystal layer 564 to hold a cell gap. The transistor 557 is covered with insulating layers 558a and 558b each provided with a contact hole. The electrode 554 and the pixel electrode 559 are electrically connected to each other. The insulating layer covering the transistor may have a multilayer structure composed of the insulating layers 558a and 558b as shown in FIG. 6B, alternatively, a single layer structure composed of the insulating layer 528 as shown in FIG. 6A. The insulating layer covering the transistor may be a layer with a flattened surface like the insulating layer 558b as shown in FIG. 6B. The counter electrode 562 is supported by an opposing substrate 561. In the transistor 557, a semiconductor layer 556 is overlapped with a gate electrode 552 via a gate insulating layer 553.

The structure of the liquid crystal display device is not restricted. Other than the mode described in this embodiment mode, for example, the liquid crystal display device may have a structure in which a driver circuit over an element substrate.

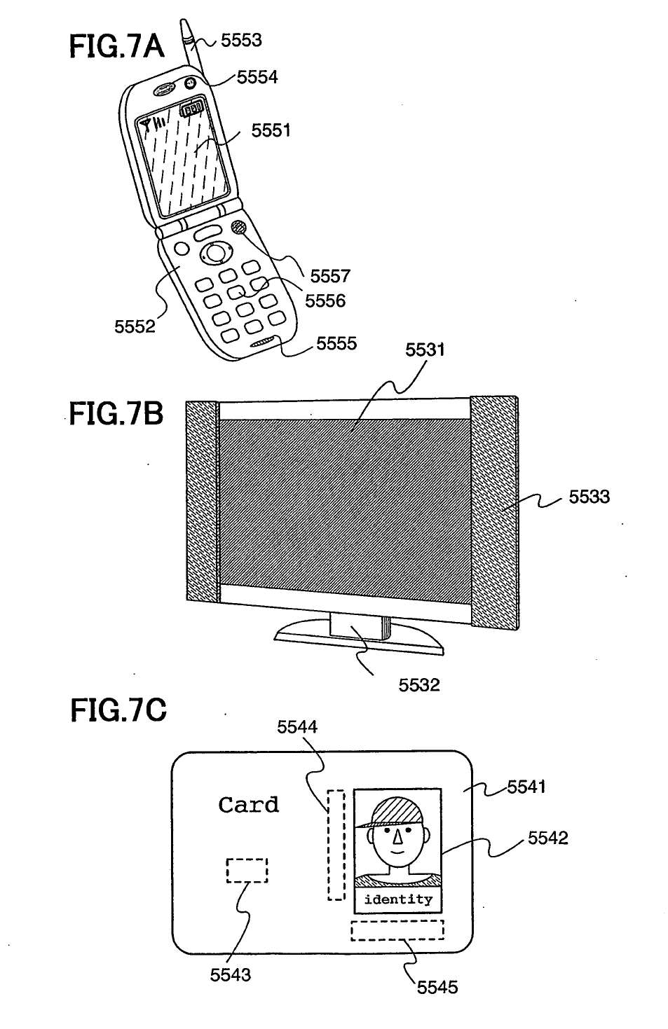

A liquid crystal display device as noted above can be used as a display device mounted on a telephone set, a television set, or the like as shown in FIGS. 7A to 7C. The liquid crystal display device can also be mounted on a card or the like having a function of managing private information such as an ID card.

FIG. 7A shows a telephone set. A main body 5552 of the telephone set includes a display area 5551, an audio output portion 5554, an audio input portion 5555, operation switches 5556 and 5557, an antenna 5553, and the like. The telephone set has good operational characteristics and high reliability. The telephone set can be completed by incorporating a semiconductor device according to the present invention into the display area.

FIG. 7B illustrates a television set manufactured by applying the present invention. The television set comprises a display area 5531, a housing 5532, a speaker 5533, and the like. The television set has good operational characteristics and high reliability. The television set can be completed by incorporating a light emitting device including a light emitting element according to the present invention for the display area.

FIG. 7C illustrates an ID card manufactured by applying the present invention. The ID card comprises a support medium 5541, a display area 5542, an integrated circuit chip 5543, or the like incorporated into the support medium 5541. Integrated circuits 5544 and 5545 for driving the display area 5542 are also incorporated into the support medium 5541. The ID card has high reliability. For example, what kind of information is input or output can be confirmed by displaying information input to or output from the integrated circuit chip 5543 on the display area 5542.

### Embodiment 1

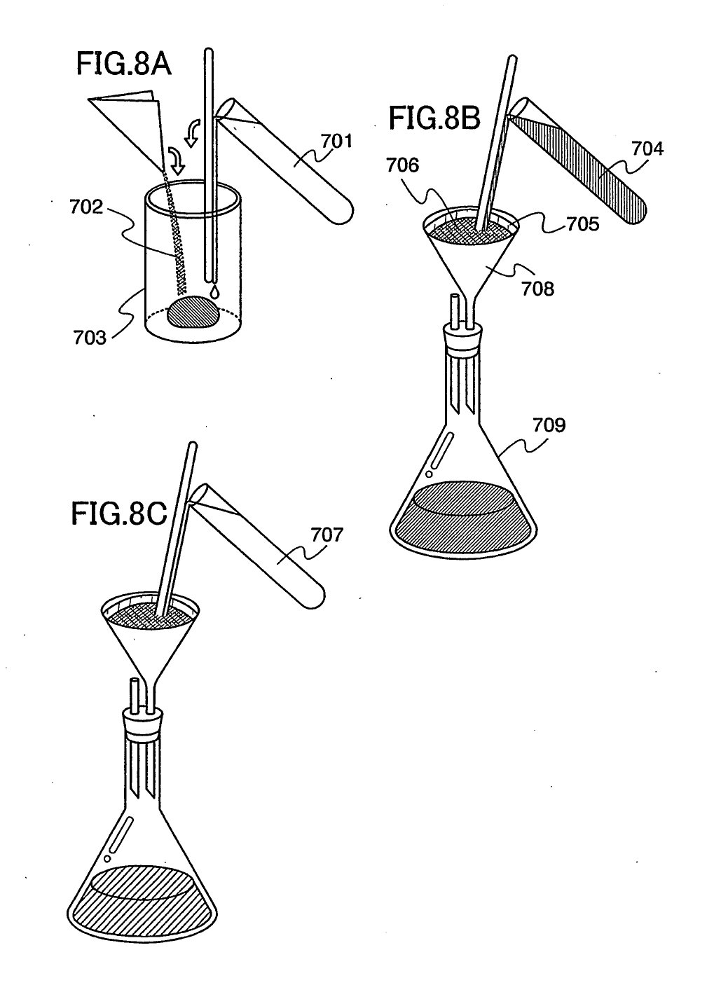

A method for purifying a material comprising pentacene according to the invention will be described with reference to FIGS. 8A to 8C. Note that the invention is not limited to what is shown here.

200 ml dimethyl sulfoxide solution 701 and 0.5 g pentacene 702 which was an object of a purification were mixed in a beaker 703, and the solution was referred to as a solution (1) (first treatment, FIG. 8A).

Next, the solution (1) 704 was filtered using a filter paper 705 (pore size of 1 μm or less) placed in a funnel 708. Thus, pentacene that was dispersed without being dissolved in the dimethyl sulfoxide solution and the dimethyl sulfoxide solution which accumulates in a flask 709 are separated (second treatment, FIG. 8B).

Subsequently, pentacene 706 obtained by the filtration was washed (cleaned) with ethanol 707 to remove dimethyl sulfoxide attached to pentacene. It is hard to remove dimethyl sulfoxide because dimethyl sulfoxide has a high boiling point. Therefore, pentacene 706 is washed with ethanol 707 has a low boiling point. (third treatment, FIG. 8C) Pentacene is thereafter dried under reduced pressure (fourth treatment).

The above described first to fourth treatments were repeated four times. Thus, 0.45 g pentacene (pentacene (1)) is obtained.

### Embodiment 2

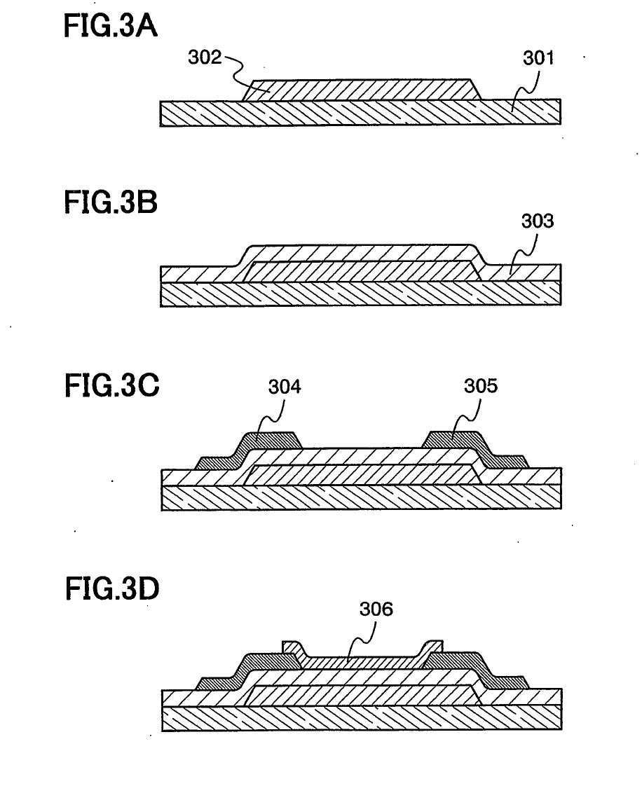

A semiconductor device using pentacene obtained according to Embodiment 1 and a manufacturing method thereof will be described with reference to FIGS. 3A to 3D.

A tungsten film was formed over a substrate 301 by sputtering to form a gate electrode 302. Here, the tungsten film was formed to a thickness of 100 nm. (FIG. 3A)

A silicon oxide film was formed to cover the gate electrode 302 by CVD thereby forming a gate insulating layer 303. Here, the silicon oxide film was formed to a thickness of 100 nm. (FIG. 3B)

Next, a tungsten film was formed over the gate insulating layer 303 by sputtering to form a source electrode 304 and a drain electrode 305. Here, the tungsten film was formed to a thickness of 100 nm. Apart of each of the source electrode 304 and the drain electrode 305 was made to overlap with the gate electrode 302. (FIG. 3C)

Subsequently, pentacene (1) was deposited to a thickness of 50 nm so as to cover the overlapping portion of the gate insulating layer 303 and the gate electrode 302 thereby forming a semiconductor layer 306. Here, the film formation was carried out by vapor deposition. Further, a stack portion is provided so that the semiconductor layer 306 was partially in contact with the source electrode 304. Further, another stack portion was formed so that the semiconductor layer 306 is partially in contact with the drain electrode 305. (FIG. 3D)

As described above, a p-channel semiconductor device is manufactured.

### Comparative Example 1

As a comparative example of the semiconductor device described in Embodiment 2, a semiconductor device was manufactured using pentacene (pentacene (2)) that was obtained after repeating sublimation purification four times. The semiconductor device was manufactured in the same manner as Embodiment 2 except that the semiconductor layer 306 is formed of pentacene (2) instead of pentacene (1).

### Comparative Example 2

As another comparative example of the semiconductor device described in Embodiment 2, a semiconductor device was manufactured using unpurified pentacene (pentacene (3)) without being subjected to sublimation purification or purification described in Embodiment 1. The semiconductor device was manufactured in the same manner as Embodiment 2 except that the semiconductor layer 306 is formed of pentacene (3) instead of pentacene (1).

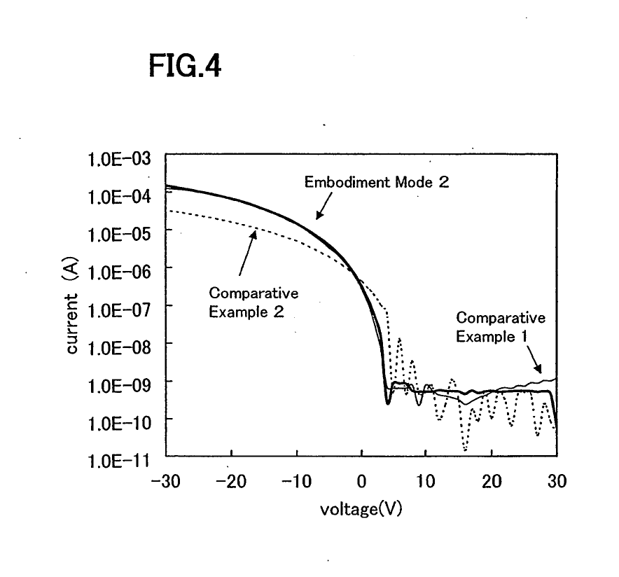

The voltage-current characteristics of each semiconductor device manufactured as described above (Embodiment 1, Comparative Example 1, and Comparative Example 2) are shown in FIG. 4. In FIG. 4, the horizontal axis indicates voltage (V) and the vertical axis indicates current (A). Moreover, a thick solid line indicates the characteristics of the semiconductor device according to Embodiment 2, a thin solid line indicates the characteristics of the semiconductor device of Comparative Example 1, a thin dotted line indicates the characteristics of the semiconductor device of Comparative Example 2. Here, a semiconductor device with the channel length (L) and the channel width (W) of L=50 μm and W=8000 μm was used.

As shown in FIG. 4, the semiconductor device of Embodiment 2 and the semiconductor device of Comparative Example 1 have similar threshold values and on-state current and thus display the similar voltage-current characteristics. On the other hand, the semiconductor device of Comparative Example 2 is much lower in on-state current than the semiconductor device of Embodiment 2 or Comparative Example 1.

From the results above, it is understood that a semiconductor device having good characteristics can be obtained by forming a semiconductor layer using pentacene obtained by a purification method according to the invention.

This application is based on Japanese Patent Application serial no. 2004-242792 filed in Japan Patent Office on Aug. 23, 2004, the entire contents of which are hereby incorporated by reference.

1. A method for purifying a material comprising an organic semiconductor, comprising:
mixing a material comprising the organic semiconductor in a sulfoxide solution; and
filtering the sulfoxide solution mixed with the organic semiconductor.

2. A method for purifying a material comprising an organic semiconductor, comprising:
forming a solution by mixing the material comprising the organic semiconductor in a sulfoxide solution;
filtering the solution; and
washing the organic semiconductor separated from the sulfoxide solution with an alcohol solution after filtering and thereafter drying the washed organic semiconductor.

3. A method for purifying a material comprising a pentacene, comprising:
mixing the material comprising the pentacene in a sulfoxide solution; and
filtering the sulfoxide solution mixed with the pentacene.

4. A method for purifying a material comprising a pentacene, comprising:
forming a solution by mixing the material comprising the pentacene in a sulfoxide solution;
filtering the solution; and
washing the pentacene separated from the sulfoxide solution with an alcohol solution after filtering and thereafter drying the washed pentacene.

5. A method for purifying a material comprising an organic semiconductor according to claim 1,
wherein the sulfoxide solution is a dimethyl sulfoxide solution.

6. A semiconductor device comprising:
a semiconductor layer,
wherein the semiconductor layer contains an organic semiconductor obtained by filtering a sulfoxide solution mixed with a material comprising the organic semiconductor.

7. A semiconductor device comprising:
a semiconductor layer,
wherein the semiconductor layer contains a pentacene obtained by filtering a sulfoxide solution mixed with a material comprising the pentacene.

8. A semiconductor device comprising:
a gate electrode, a drain electrode, a source electrode, a semiconductor layer, and a gate insulating layer provided between the gate electrode and the semiconductor layer,
wherein the drain electrode and the source electrode are each in contact with the semiconductor layer; and
wherein the semiconductor layer contains an organic semiconductor obtained by filtering a sulfoxide solution mixed with a material comprising the organic semiconductor.

9. A semiconductor device comprising:
a gate electrode, a drain electrode, a source electrode, a semiconductor layer, a gate insulating layer provided between the gate electrode and the semiconductor layer,
wherein the drain electrode and the source electrode are each in contact with the semiconductor layer; and
wherein the semiconductor layer contains a pentacene obtained by filtering a sulfoxide solution mixed with a material comprising the pentacene.

10. An electronic device wherein a semiconductor device according to claim 6 is used as a circuit element.

11. An electronic device wherein a semiconductor device according to claim 7 is used as a circuit element.

12. An electronic device wherein a semiconductor device according to claim 8 is used as a circuit element.

13. An electronic device wherein a semiconductor device according to claim 9 is used as a circuit element.

14. A method for purifying a material comprising an organic semiconductor according to claim 2, wherein the sulfoxide solution is a dimethyl sulfoxide solution.

15. A method for purifying a material comprising a pentacene according to claim 3, wherein the sulfoxide solution is a dimethyl sulfoxide solution.

16. A method for purifying a material comprising a pentacene according to claim 4, wherein the sulfoxide solution is a dimethyl sulfoxide solution.

17. A method for purifying a material comprising an organic semiconductor according to claim 1, wherein the sulfoxide solution is filtered by a filter paper or a membrane filter.

18. A method for purifying a material comprising an organic semiconductor according to claim 2, wherein the sulfoxide solution is filtered by a filter paper or a membrane filter.

19. A method for purifying a material comprising a pentacene according to claim 3, wherein the sulfoxide solution is filtered by a filter paper or a membrane filter.

20. A method for purifying a material comprising a pentacene according to claim 4, wherein the sulfoxide solution is filtered by a filter paper or a membrane filter.

21. A method for fabricating a semiconductor device comprising;
forming a gate electrode over a substrate;
forming a gate insulating layer to be in contact with the gate electrode;
forming a semiconductor layer comprising a organic semiconductor obtained by filtering a sulfoxide solution mixed with a material comprising the organic semiconductor, a source electrode, and a drain electrode to be in contact with the gate insulating layer;
wherein the source and drain electrodes are electrically in contact with the organic semiconductor.

22. A method for fabricating a semiconductor device comprising;
forming a gate electrode over a substrate;
forming a gate insulating layer over the gate electrode;
forming a semiconductor layer comprising a organic semiconductor obtained by filtering a sulfoxide solution mixed with a material comprising the organic semiconductor, a source electrode, and a drain electrode over the gate insulating layer;
wherein the source and drain electrodes are electrically in contact with the organic semiconductor.

23. A method for fabricating a semiconductor device according to claim 21, wherein parts of the source and drain electrodes are formed over parts of the semiconductor layer.

24. A method for fabricating a semiconductor device according to claim 22, wherein parts of the source and drain electrodes are formed over parts of the semiconductor layer.

25. A method for fabricating a semiconductor device according to claim 21, wherein parts of the semiconductor layer are formed over parts of the source and drain electrodes.

26. A method for fabricating a semiconductor device according to claim 22, wherein parts of the semiconductor layer are formed over parts of the source and drain electrodes.

27. A method for fabricating a semiconductor device according to claim 21, wherein the organic semiconductor is pentacene.

28. A method for fabricating a semiconductor device according to claim 22, wherein the organic semiconductor is pentacene.

29. A method for fabricating a semiconductor device according to claim 21, wherein the semiconductor layer is formed further by washing the organic semiconductor separated from the sulfoxide solution with an alcohol solution after filtering and thereafter drying the washed organic semiconductor.

30. A method for fabricating a semiconductor device according to claim 22, wherein the semiconductor layer is formed further by washing the organic semiconductor separated from the sulfoxide solution with an alcohol solution after filtering and thereafter drying the washed organic semiconductor.
